(19) United States
(12) Patent Application Publication
(10) Pub. No.: US 2025/0220977 A1
(43) Pub. Date: Jul. 3, 2025

(54) SEMICONDUCTOR DEVICE AND ELECTRONIC APPARATUS INCLUDING THE SAME

(71) Applicant: Samsung Electronics Co., Ltd., Suwon-si (KR)

(72) Inventors: Sanghyun JO, Suwon-si (KR); Hyangsook LEE, Suwon-si (KR); Kihong KIM, Suwon-si (KR); Seunggeol NAM, Suwon-si (KR); Sangjun LEE, Suwon-si (KR)

(73) Assignee: Samsung Electronics Co., Ltd., Suwon-si (KR)

(21) Appl. No.: 18/989,716

(22) Filed: Dec. 20, 2024

(30) Foreign Application Priority Data
Dec. 27, 2023 (KR) 10-2023-0193169

(51) Int. Cl. H10D 30/67; H10D 30/43; H10D 30/62

(52) U.S. Cl. CPC H10D 30/6756; H10D 30/6757; H10D 30/43; H10D 30/62; H10D 30/6735

(57) ABSTRACT

Provided are a semiconductor device and an electronic apparatus including the semiconductor device. The semiconductor device includes a substrate on which a channel layer is provided, an amorphous thin film provided above the substrate, and a gate electrode provided above the amorphous thin film. The amorphous thin film includes an amorphous Hf₁₋ₓZrₓO₂ (0≤x≤1) layer, and a difference value ΔE of a d-orbital with respect to Hf or Zr (an energy difference between an eg orbital and a t2g orbital) satisfies 3.5 eV≤ΔE<3.8 eV.

### CROSS-REFERENCE TO RELATED APPLICATION

This application claims the benefit of Korean Patent Application No. 10-2023-0193169, filed on Dec. 27, 2023, in the Korean Intellectual Property Office, the disclosure of which is incorporated herein in its entirety by reference.

### BACKGROUND

### 1. Field

The disclosure relates to a semiconductor device and an electronic apparatus including the semiconductor device.

### 2. Description of the Related Art

In existing semiconductor devices, as scaling down reaches limitations and/or power consumption gradually increases, various studies on lower-power semiconductor devices have been performed. Lower-power semiconductor devices are being developed to improve performance and/or overcome the scaling-down limitations by utilizing the negative capacitance phenomenon of ferroelectric thin films.

### SUMMARY

Provided are a semiconductor device and an electronic apparatus including the semiconductor device.

Additional aspects will be set forth in part in the description which follows and, in part, will be apparent from the description, or may be learned by practice of the presented embodiments.

According to an aspect of the disclosure, a semiconductor device includes a substrate including a channel layer; a gate electrode over the channel layer; and an amorphous thin film between the substrate and the gate electrode, wherein the amorphous thin film includes an amorphous Hf₁₋ₓZrₓO₂ (0≤x≤1) layer, a difference value ΔE of a d-orbital with respect to at least one of the Hf or the Zr satisfies 3.5 eV<ΔE<3.8 eV, and the difference value ΔE represents an energy difference between an eg orbital and a t2g orbital with respect to the at least one of the Hf or the Zr.

The difference value ΔE may satisfy 3.6 eV≤ΔE≤3.75 eV.

The amorphous thin film may further include a dopant of at least one of Si, Al, Y, La, or Gd.

The amorphous thin film may have the thickness within a range of 0.5 nm to 20 nm.

The amorphous thin film may have the thickness within a range of 0.5 nm to 3 nm.

The amorphous thin film may have the thickness within a range of 3 nm to 20 nm.

The amorphous thin film may include an amorphous Hf₁₋ₓZrₓO₂ (0<x<1) layer in which amorphous ZrO₂ and amorphous HfO₂ are alternately stacked. The amorphous thin film may further include an amorphous ZrO₂ layer provided on a lower surface of the amorphous Hf₁₋ₓZrₓO₂ (0<x<1) layer.

A source and a drain are provided on both sides of the channel layer.

The channel layer may include at least one of Si, Ge, SiGe, a group III-V semiconductor, an oxide semiconductor, a nitride semiconductor, an oxynitride semiconductor, a two-dimensional (2D) semiconductor material, quantum dots, or an organic semiconductor.

The gate electrode may include at least one of a metal, a conductive metal nitride, a conductive metal carbide, polysilicon, or a two-dimensional conductive material.

The semiconductor device may further include a first dielectric layer between the channel layer and the amorphous thin film.

The first dielectric layer may include at least one of silicon oxide, silicon nitride, aluminum oxide, silicon oxynitride, lanthanum oxide, or yttrium oxide.

The semiconductor device may further include a second dielectric layer between the amorphous thin film and the gate electrode.

According to another aspect of the disclosure, a semiconductor device includes a substrate including a channel layer; a gate electrode over the channel layer; and an amorphous thin film provided between the substrate and the gate electrode, wherein the amorphous thin film comprises an amorphous Hf₁₋ₓZrₓO₂ (0<x<1) layer and an amorphous ZrO₂ layer between the amorphous Hf₁₋ₓZrₓO₂ (0<x<1) layer and the channel layer.

A difference value ΔE of a d-orbital with respect to Hf or Zr (an energy difference between an eg orbital and a t2g orbital) in the amorphous Hf₁₋ₓZrₓO₂ (0<x<1) layer may satisfy 3.5 eV<ΔE<3.8 eV.

The difference value ΔE may satisfy 3.6 eV<ΔE<3.75 eV.

The amorphous thin film may further include a dopant of at least one of Si, Al, Y, La, or Gd.

The amorphous thin film may have the thickness within a range of 0.5 nm to 20 nm.

According to another aspect of the disclosure, an electronic apparatus includes the semiconductor device described above.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view of a semiconductor device according to at least one embodiment;

FIG. 2A is a transmission electron microscopy (TEM) image showing a cross-section of a metal-oxide-semiconductor capacitor (MOSCAP) including an amorphous HZO layer;

FIG. 2B is a TEM image showing a cross-section of a MOSCAP including an amorphous ZrO₂/HZO layer;

FIG. 2C is a graph showing a result of in-plane X-ray diffraction (XRD) measurement of the ZrO₂/HZO layer illustrated in FIG. 2B;

FIG. 3A is a TEM image showing a cross-section of a MOSCAP including a crystalline ZrO₂ layer;

FIG. 3B are images showing results of fast Fourier transform (FFT) of the ZrO₂ layer illustrated in FIG. 3A;

FIG. 4A is a graph showing a result of measuring capacitance (C)—voltage (V) characteristics of the MOSCAP including a crystalline ZrO₂ layer, the MOSCAP including an amorphous HZO layer, and the MOSCAP including an amorphous ZrO₂/HZO layer;

FIG. 4B is a graph showing a result of measuring current (I)—voltage (V) characteristics of the MOSCAP including a crystalline ZrO₂ layer, the MOSCAP including an amorphous HZO layer, and the MOSCAP including an amorphous ZrO₂/HZO layer;

FIG. 5 is a graph showing a result of measuring gate leakage current (Jg)—equivalent oxide thickness (EOT) characteristics of a crystalline (rhombic system) ZrO₂/HZO layer and an amorphous ZrO₂/HZO layer;

FIG. 6 is a graph showing a result of measuring capacitance (C)—voltage (V) characteristics of a MOSCAP including an amorphous ZrO₂ layer and a MOSCAP including an amorphous ZrO₂/HZO layer;

FIGS. 7A and 7B are graphs showing results of X-ray absorption spectroscopy (XAS) measurement of example samples of the amorphous ZrO₂/HZO layer;

FIG. 8 is a graph showing a difference value ΔE of example samples of the amorphous ZrO₂/HZO layer calculated through the XAS measurement results;

FIG. 9 is a schematic cross-sectional view of a semiconductor device according to at least one embodiment;

FIG. 10 is a schematic cross-sectional view of a semiconductor device according to at least one embodiment;

FIG. 11 is a schematic cross-sectional view of a semiconductor device according to at least one embodiment;

FIGS. 12 and 13 are respectively a perspective view and a cross-sectional view schematically showing a semiconductor device according to at least one embodiment;

FIGS. 14 and 15 are schematic views of a semiconductor device according to at least one embodiment;

FIG. 16 illustrates a semiconductor apparatus according to at least one embodiment; and

FIGS. 17 and 18 are conceptual block diagrams schematically showing a device architecture to be applied to an electronic apparatus according to at least one embodiment.

### DETAILED DESCRIPTION

Reference will now be made in detail to embodiments, examples of which are illustrated in the accompanying drawings. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments are described in detail with reference to the accompanying drawings. Throughout the drawings, like reference numerals denote like elements, and sizes of components in the drawings may be exaggerated for convenience of explanation and clarity. As embodiments described below are examples, other modifications may be produced from the embodiments. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, “within the range of ‘X’ to ‘Y” includes all values between X and Y, including X and Y.

When a constituent element is disposed “above” or “on” to another constituent element, the constituent element may include not only an element directly contacting on the upper, lower, left, and right sides of the other constituent element, but also an element disposed above, under, on the left side of, and on the right side of the other constituent element in a non-contact manner. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. As used herein, the singular forms “a,” “an,” and “the” are intended to include the plural forms as well, unless the context clearly indicates otherwise. Furthermore, it will be further understood that the terms “comprises” and/or “comprising” used herein specify the presence of stated features or elements, but do not preclude the presence or addition of one or more other features or elements.

The use of the terms “a,” “an,” “the,” and similar referents in the context of describing the disclosure is to be construed to cover both the singular and the plural. Also, the operations of all methods described herein can be performed in any suitable order unless otherwise indicated herein or otherwise clearly contradicted by context. The disclosure is not limited to the described order of the steps.

Furthermore, terms such as “ . . . portion,” “ . . . unit,” “ . . . module,” and “ . . . block” stated in the disclosure may signify a functional unit configured to process at least one function or operation and the unit may be embodied by processing circuitry such as hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc., and/or, as described in further detail below, may include active and/or passive elements such as transistors, gates, capacitors, resistors, and/or the like.

Furthermore, the connecting lines, or connectors shown in the various figures presented are intended to represent functional relationships and/or physical or logical couplings between the various elements. It should be noted that many alternative or additional functional relationships, physical connections or logical connections may be present in a practical device.

The use of any and all examples, or language (e.g., “such as”) provided herein, is intended merely to better illuminate the disclosure and does not pose a limitation on the scope of the disclosure unless otherwise claimed.

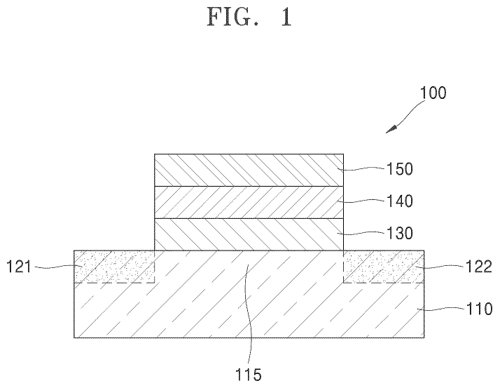

FIG. 1 is a schematic view of a semiconductor device 100 according to at least one embodiment. The semiconductor device 100 illustrated in FIG. 1 may include, for example, a field effect transistor (FET).

Referring to FIG. 1, the semiconductor device 100 may include a substrate 110, an amorphous thin film 140, and a gate electrode 150. A dielectric layer 130 may be provided between the substrate 110 and the amorphous thin film 140.

A channel layer 115 is provided in and/or on an upper region of the substrate 110, and a source 121 and a drain 122 are provided on both sides of the channel layer 115. The channel layer 115 is provided to correspond with the gate electrode 150.

The source 121 may be electrically connected to a first side of the channel layer 115, and the drain 122 may be electrically connected to a second side of the channel layer 115. The first and second sides may be opposite to each other. In at least some embodiments, the source 121 and drain 122 may be formed by injecting impurities into different regions of the substrate 110, and a region of the substrate 110 between the source 121 and the drain 122 may be defined as the channel layer 115. In at least some embodiments, the channel layer 115 may be integrally provided with the substrate 110. However, the example embodiments are not limited thereto, and the channel layer may be provided as a material layer separate from the substrate 110 (e.g., not as a part of the substrate 110).

The substrate 110 including the channel layer 115 may include a semiconductor material. For example, the substrate 110 may include, for example, an elemental semiconductor (e.g., Si, Ge, SiGe, etc.), a compound semiconductor (e.g., one or more of the group III-V semiconductors), an oxide semiconductor, a nitride semiconductor, an oxynitride semiconductor, a two-dimensional (2D) semiconductor material, quantum dots, an organic semiconductor, and/or the like. The oxide semiconductors may include, for example, InGaZnO, the two-dimensional semiconductor materials may include, for example, transition metal dichalcogenide (TMD) and/or graphene, and the quantum dots may include colloidal QDs, or nanocrystal structures. However, these are just examples, and the disclosure is not limited thereto.

The substrate 110 including the channel layer 115 may include a dopant of a certain concentration. The dopant may include a p-type dopant and/or an n-type dopant. The p-type dopant may include, for example, a group III element, such as B, Al, Ga, or In, and the n-type dopant may include, for example, a group V element, such as P, As, or Sb.

When a semiconductor substrate including a p-type dopant is used as the substrate 110, and the source 121 and drain 122 include n-type impurities, the semiconductor device 100 of a p-channel metal-oxide-semiconductor (PMOS) structure may be implemented. Alternatively, when a semiconductor substrate including an n-type dopant is used as the substrate 110, and when the source 121 and drain 122 include p-type impurities, the semiconductor device 100 of an n-channel metal-oxide-semiconductor (NMOS) structure may be implemented.

The gate electrode 150 is provided spaced apart from the substrate 110. The gate electrode 150 may be disposed to face the channel layer 115 of the substrate 110. The gate electrode 150 may include, for example, a conductive material, such as a metal, a metal nitride, a metal carbide, polysilicon, a two-dimensional conductive material, and/or the like. For example, the gate electrode 150 may include metal and/or metal nitride. The metal may include, for example, aluminum (Al), tungsten (W), molybdenum (Mo), titanium (Ti), tantalum (Ta), and/or the like, and the metal nitride may include, for example, titanium nitride (TiN), tantalum nitride (TaN), and/or the like. For example, the gate electrode 150 may include metal carbide, polysilicon, and/or a two-dimensional conductive material. The metal carbide may be metal carbide doped with aluminum or silicon. As a detailed example, the metal carbide may include TiAlC, TaAlC, TiSiC, TaSiC, and/or the like. The gate electrode 150 may have a structure in which a plurality of materials are stacked. For example, the gate electrode 150 may have a stack structure of a metal nitride layer/a metal layer, such as TiN/Al, or a stack structure of a metal nitride layer/a metal carbide layer/a metal layer, such as TiN/TiAlC/W.

The dielectric layer 130, which may also be referred to as an interface layer, may be provided on an upper surface of the substrate 110. The dielectric layer 130 may not include a ferroelectric material. For example, the dielectric layer 130 may include a paraelectric material. As a detailed example, the dielectric layer 130 may include at least one of silicon oxide, silicon nitride, aluminum oxide, silicon oxynitride, lanthanum oxide, yttrium oxide, and/or the like. However, the examples are not limited thereto.

The amorphous thin film 140 may be provided between the dielectric layer 130 and the gate electrode 150. The amorphous thin film 140 may include an amorphous Hf₁₋ₓZrₓO₂ (0≤x≤1) layer. In detail, the amorphous thin film 140 may include an amorphous HfO₂ layer, an amorphous ZrO₂ layer, and/or an amorphous HZO layer. The “amorphous HZO layer” refers to an amorphous Hf₁₋ₓZrₓO₂ (0<x<1) layer having a structure in which amorphous HfO₂ and amorphous ZrO₂ are alternately deposited.

In the amorphous Hf₁₋ₓZrₓO₂ (0<x<1) layer, ΔE of a d-orbital with respect to Hf or Zr may satisfy 3.5 eV<ΔE<3.8 eV. The “ΔE” denotes a difference value between the energy of an eg orbital and the energy of a t2g orbital. For example, the difference value (ΔE) of a d-orbital with respect to Hf or Zr may satisfy 3.6 eV≤ΔE≤3.75 eV.

The amorphous thin film 140 may be formed by depositing an Hf₁₋ₓZrₓO₂ (0≤x≤1) layer on an upper surface of the dielectric layer 130 and then heat-treating the Hf₁₋ₓZrₓO₂ (0≤x≤1) layer. In this state, the Hf₁₋ₓZrₓO₂ (0≤x≤1) layer may be deposited by, for example, atomic layer deposition (ALD), metal organic atomic layer deposition (MOALD), chemical vapor deposition (CVD), or physical vapor deposition (PVD). However, the disclosure is not limited thereto.

The amorphous Hf₁₋ₓZrₓO₂ (0≤x≤1) layer may be formed by heat-treating the Hf₁₋ₓZrₓO₂ (0≤x≤1) layer deposited on the upper surface of the dielectric layer 130 to a certain temperature. Before the deposition of the gate electrode 150 after the Hf₁₋ₓZrₓO₂ (0≤x≤1) layer is deposited, a heat-treatment process, that is, post deposition annealing (PDA), may be performed. In this case, the heat-treatment may be performed at a temperature lower than a heat-treatment temperature at which the Hf₁₋ₓZrₓO₂ (0≤x≤1) layer has crystallinity. In other words, the heat-treatment may be performed at a temperature wherein the crystallization (e.g., grain propagation) of the Hf₁₋ₓZrₓO₂ (0≤x≤1) in the Hf₁₋ₓZrₓO₂ (0≤x≤1) layer is prevented and/or negligible. Meanwhile, even after the deposition of the gate electrode 150, an additional heat-treatment process, that is, post metallization annealing (PMA), may be performed.

The amorphous Hf₁₋ₓZrₓO₂ (0≤x≤1) layer may further include, for example, at least one dopant of Si, Al, Y, La, and Gd. The doping of the dopant may be performed by, for example, ion implantation or plasma treatment. However, the disclosure is not limited thereto.

When an electric field is applied to the amorphous Hf₁₋ₓZrₓO₂ (0≤x≤1) layer, an ordered dipole cluster may be formed, and hysteresis may occur by the ordered dipole cluster. Furthermore, the amorphous Hf₁₋ₓZrₓO₂ (0≤x≤1) layer may have a double-well type potential landscape on an electric charge (Q) and energy (U) curve, and a negative capacitance effect may occur in a negative capacitance region of a double-well potential.

The amorphous thin film 140 including the amorphous Hf₁₋ₓZrₓO₂ (0≤x≤1) layer may have, for example, a thickness within a range of 0.5 nanometers (nm) to 20 nm. For example, the amorphous thin film 140 may have a thickness within a range of 0.5 nm to 3 nm or a thickness within a range of 3 nm to 20 nm, according to the use of the semiconductor device 100.

The amorphous thin film 140 may include the amorphous ZrO₂/HZO layer. The “amorphous ZrO₂/HZO layer” refers to an amorphous ZrO₂ layer and an amorphous HZO layer formed on an upper surface of the amorphous ZrO₂ layer. The amorphous ZrO₂ layer in the amorphous ZrO₂/HZO layer may have a thickness greater than the amorphous ZrO₂ alternately stacked with the amorphous HfO₂ layer in the amorphous HZO layer.

In general, hafnium oxide, zirconium oxide, or hafnium-zirconium oxide, when crystalline and ferroelectric, may have an affinity to a semiconductor process, enable scaling down of a device, and implement lower-power driving of a device by a negative capacitance effect. However, the ferroelectric material is most manufactured of a polycrystalline thin film by the ALD, and the polycrystalline thin film has a problem in that a leakage current through a crystal grain boundary increases.

In the present example embodiments, by using the amorphous thin film 140 including the amorphous Hf₁₋ₓZrₓO₂ (0≤x≤1) layer as a gate insulating layer provided between the substrate 110 and the gate electrode 150, a negative capacitance effect may be obtained, and the semiconductor device 100 may be implemented, which may reduce a leakage current compared with the ferroelectric thin film including crystalline ferroelectric materials.

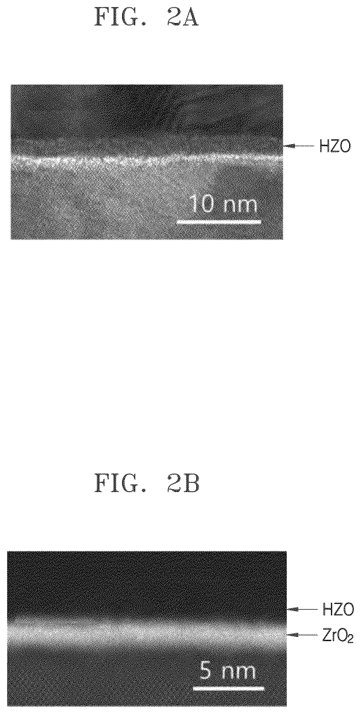

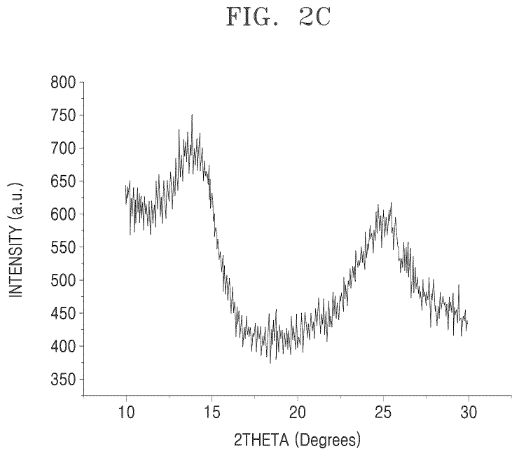

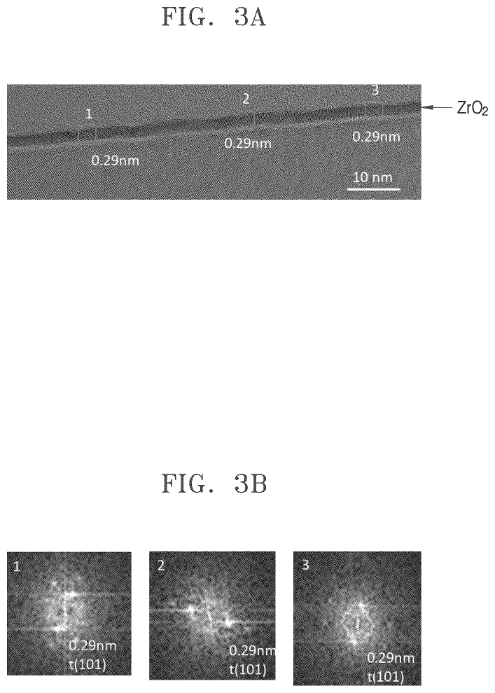

FIG. 2A shows a transmission electron microscopy (TEM) image showing a cross-section of the metal-oxide-semiconductor capacitor (MOSCAP) including the amorphous HZO layer. FIG. 2B shows a TEM image showing a cross-section of the MOSCAP including an amorphous ZrO₂/HZO layer.

FIG. 2C is a graph showing results of in-plane X-ray diffraction (XRD) of measurement of the ZrO₂/HZO layer illustrated in FIG. 2B. Referring to FIG. 2C, it may be seen that the ZrO₂/HZO layer illustrated in FIG. 2B is an amorphous material.

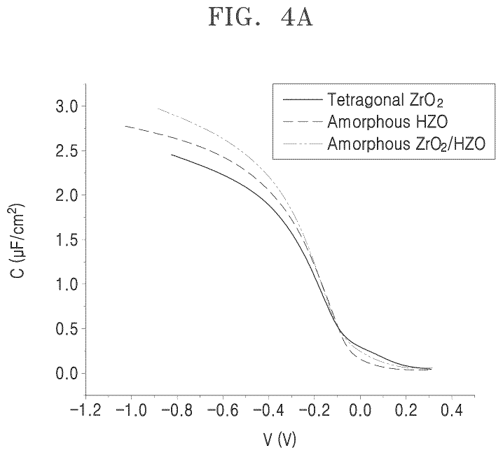

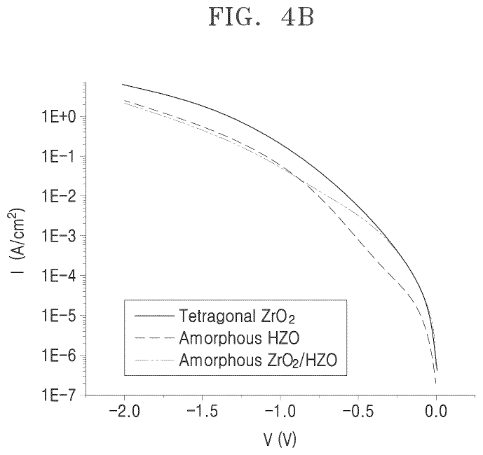

FIG. 3A is a TEM image showing a cross-section of the MOSCAP including a crystalline ZrO₂ layer. In FIG. 3A, “1,” “2,” and “3” denote three positions arbitrarily selected from the crystalline ZrO₂ thin film. In FIG. 3A, a lattice constant (that is, a distance between crystal planes) at each of the positions “1,” “2,” and “3” are measured to be 0.29 nm.

FIG. 3B are images showing results of fast Fourier transform (FFT) at the positions “1,” “2,” and “3” of the crystalline ZrO₂ layer illustrated in FIG. 3A. Referring to FIG. 3B, it may be seen that the ZrO₂ layer illustrated in FIG. 3A has a crystal structure of a tetragonal crystal system. In the image of FIG. 3B, “t(101)” denotes a (101) crystal plane in the tetragonal crystal system.

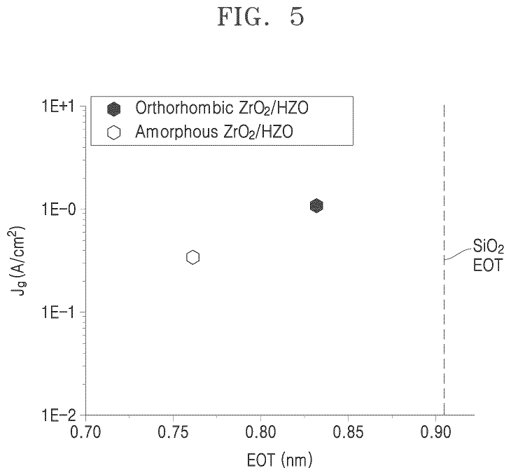

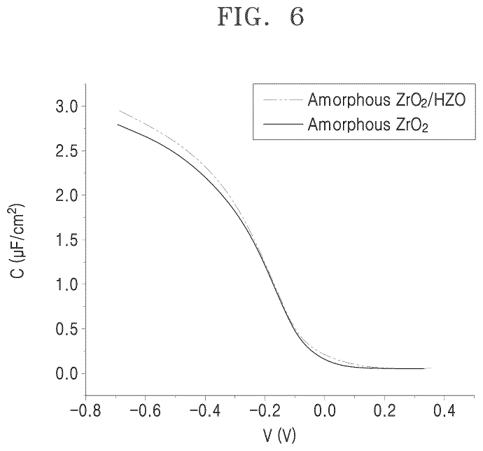

FIGS. 4A and 4B are graphs showing results of electrical measurements on the MOSCAP including a crystalline ZrO₂ layer, the MOSCAP including an amorphous HZO layer, and the MOSCAP including an amorphous ZrO₂/HZO layer. In FIGS. 4A and 4B, the crystalline ZrO₂ layer, the amorphous HZO layer, and the amorphous ZrO₂/HZO layer are respectively formed through heat-treatment at a temperature (PDA temperature) of about 700° C., about 600° C., and about 500° C.

FIG. 4A is a graph showing a result of measuring capacitance (C)—voltage (V) characteristics of the MOSCAP including a crystalline ZrO₂ layer, the MOSCAP including an amorphous HZO layer, and the MOSCAP including an amorphous ZrO₂/HZO layer. Referring to FIG. 4A, it may be seen that the crystalline (tetragonal crystal system) ZrO₂ layer (that is a ferroelectric layer), despite having a greater dielectric constant, has a lesser capacitance than those of the amorphous HZO layer and the amorphous ZrO₂/HZO layer.

FIG. 4B is a graph showing a result of measuring current (I)—voltage (V) characteristics of the MOSCAP including a crystalline ZrO₂ layer, the MOSCAP including an amorphous HZO layer, and the MOSCAP including an amorphous ZrO₂/HZO layer. Referring to FIG. 4B, it may be seen that the crystalline (tetragonal crystal system) ZrO₂ layer (that is a ferroelectric layer) has a greater leakage current than those of the amorphous HZO layer and the amorphous ZrO₂/HZO layer.

As illustrated in FIGS. 4A and 4B, it may be seen that the amorphous HZO layer or the amorphous ZrO₂/HZO layer have greater capacitance and less leakage current than the crystalline (tetragonal crystal system) ZrO₂ layer.

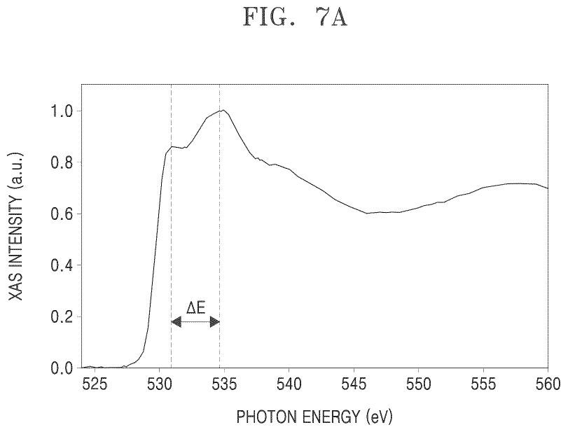

FIG. 5 is a graph showing a result of measuring gate leakage current (Jg)—equivalent oxide thickness (EOT) characteristics of a crystalline (rhombic system) ZrO₂/HZO layer and the amorphous ZrO₂/HZO layer. Referring to FIG. 5, it may be seen that the crystalline (rhombic system) ZrO₂/HZO layer (that is a ferroelectric layer) and the amorphous ZrO₂/HZO layer both have an EOT less than that of the SiO₂ layer that is an interface layer. Furthermore, it may be seen that the amorphous ZrO₂/HZO layer has a gate leakage current J_{g} and an EOT less than those of the crystalline (rhombic system) ZrO₂/HZO layer. In other words, it may be seen that, in the ZrO₂/HZO layer in an amorphous state, not only the gate leakage current J_{g} but also the EOT are reduced together compared with a case of being crystallized to be ferroelectric. Accordingly, it may be seen that the ZrO₂/HZO layer exhibits a strong negative capacitance effect in an amorphous state than a ferroelectric state. Accordingly, the ZrO₂/HZO layer may have a result of having a great negative capacitance effect and a reduced leakage current by making the layer into an amorphous state before ferroelectric crystallization is made. This is because ordered dipole clusters exit in the amorphous ZrO₂/HZO layer by performing an appropriate heat-treatment on the ZrO₂/HZO layer through the ZrO₂/HZO layer is not yet crystallized, and thus, a strong negative capacitance effect may occur by the ordered dipole clusters.

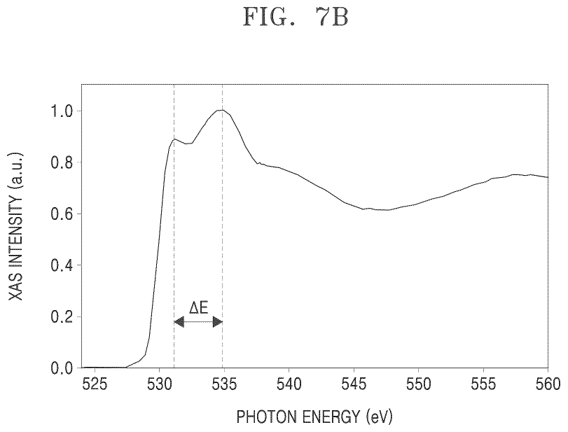

FIG. 6 is a graph showing a result of measuring capacitance (C)—voltage (V) characteristics of the MOSCAP including an amorphous ZrO₂ layer and the MOSCAP including an amorphous ZrO₂/HZO layer. In FIG. 6, the amorphous ZrO₂ layer and the amorphous ZrO₂/HZO layer are both formed through heat-treatment at a temperature (PDA temperature) of about 500° C. Referring to FIG. 6, it may be seen that the amorphous ZrO₂ layer exhibits the capacitance (C)—voltage (V) properties that are similar to those of the amorphous ZrO₂/HZO layer.

In the following description, a test result of example samples of the amorphous ZrO₂/HZO layer is presented. The example samples of the amorphous ZrO₂/HZO layer are formed by depositing a ZrO₂/HZO layer on a substrate to a thickness of 2 nm at 200° C. by using the ALD and then performing a heat-treatment on the ZrO₂/HZO layer at a temperature lower than a temperature (e.g., about 700° C.) for ferroelectric crystallization.

The example samples described below are as follows. Sample 1 #1 is an amorphous ZrO₂/HZO layer formed through heat-treatment at a first temperature (e.g., a PDA temperature of about 600° C. or less), Sample 2 #2 is an amorphous ZrO₂/HZO layer formed through heat-treatment at a second temperature (a temperature lower than the first temperature, e.g., a PDA temperature of about 500° C. or less), and Sample 3 #3 is an amorphous ZrO₂/HZO layer formed through heat-treatment at a third temperature (a temperature lower than the second temperature, e.g., a PDA temperature of about 450° C. or less). Sample 4 #4 is a ZrO₂/HZO layer in a state of being deposited on the substrate by the ALD.

In Sample 1 #1, Sample 2 #2, and Sample 3 #3, the ordered dipole cluster may be formed by an application of an electric field, and hysteresis may occur by the ordered dipole cluster. Furthermore, the electric charge (Q) and energy (U) curve may have a double-well type potential landscape, and thus, a negative capacitance effect may occur by a negative capacitance region of the double well potential.

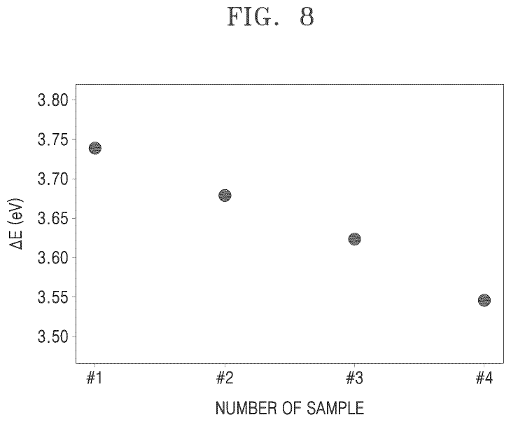

FIGS. 7A and 7B are graphs showing results of X-ray absorption spectroscopy (XAS) measurement of example samples of the amorphous ZrO₂/HZO layer. FIG. 7A shows an XAS measurement result of the amorphous ZrO₂/HZO layer of Sample 1 #1, and FIG. 7B shows an XAS measurement result of the amorphous ZrO₂/HZO layer of Sample 2 #2. A distance between two peaks in each of FIGS. 7A and 7B refers to ΔE of a d-orbital with respect to Hf or Zr. As noted above, the “ΔE” denotes an energy difference between an eg orbital and a t2g orbital.

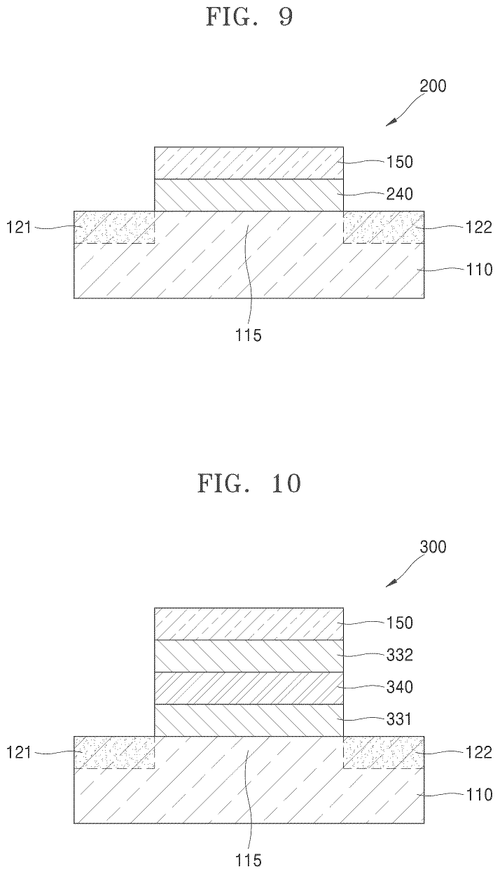

FIG. 8 is a graph showing a difference value ΔE of example samples of the amorphous ZrO₂/HZO layer calculated through the XAS measurement results. Referring to FIG. 8, in Sample 1 #1, Sample 2 #2, and Sample 3 #3, in which a negative capacitance effect may occur in the amorphous ZrO₂/HZO layer, the difference value ΔE of a d-orbital with respect to Hf or Zr may satisfy 3.5 eV<ΔE<3.8 eV. In detail, the difference value ΔE may satisfy 3.6 eV≤ΔE≤3.75 eV.

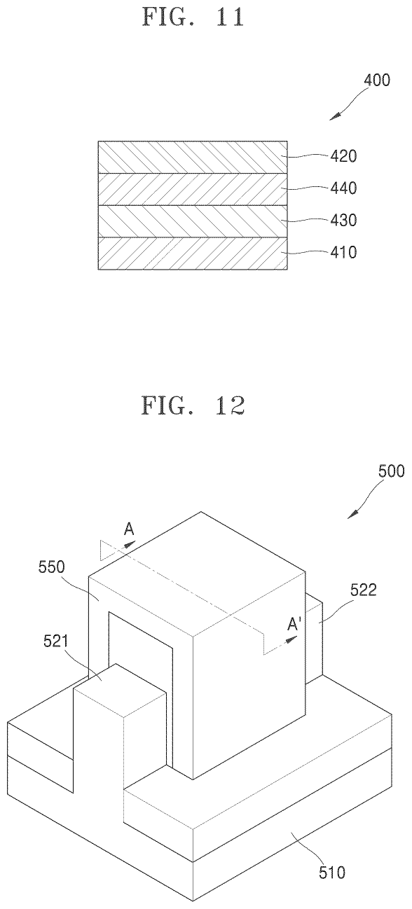

FIG. 9 is a schematic cross-sectional view of a semiconductor device 200 according to at least one embodiment. In the following description, differences from the embodiment described above are mainly described.

Referring to FIG. 9, the semiconductor device 200 may include the substrate 110, an amorphous thin film 240, and the gate electrode 150. The channel layer 115 is provided in the upper region of the substrate 110, and the source 121 and the drain 122 are provided on both sides of the channel layer 115.

The amorphous thin film 240 may include an amorphous Hf₁₋ₓZrₓO₂ (0≤x≤1) layer. In detail, the amorphous thin film 240 may include an amorphous HfO₂ layer, an amorphous ZrO₂ layer, and/or an amorphous HZO layer. In the amorphous Hf₁₋ₓZrₓO₂ (0≤x≤1) layer, the difference value ΔE of a d-orbital with respect to Hf or Zr may satisfy 3.5 eV<ΔE<3.8 eV. For example, the difference value ΔE of a d-orbital with respect to Hf or Zr may satisfy 3.6 eV≤ΔE≤3.75 eV. In at least some embodiments, the amorphous Hf₁₋ₓZrₓO₂ (0≤x≤1) layer may include, for example, at least one dopant of Si, Al, Y, La, and Gd. The amorphous thin film 240 including the amorphous Hf₁₋ₓZrₓO₂ (0≤x≤1) layer may have, for example, a thickness within a range of 0.5 nm to 20 nm. The amorphous thin film 240 may include an amorphous ZrO₂/HZO layer.

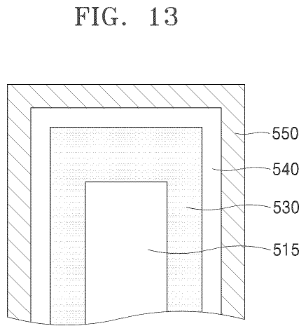

FIG. 10 is a schematic cross-sectional view of a semiconductor device 300 according to at least one embodiment. In the following description, differences from the embodiments described above are mainly described.

Referring to FIG. 10, the semiconductor device 300 may include the substrate 110, a first dielectric layer 331, an amorphous thin film 340, a second dielectric layer 332, and the gate electrode 150. The amorphous thin film 340 may include an amorphous Hf₁₋ₓZrₓO₂ (0≤x≤1) layer. In the amorphous Hf₁₋ₓZrₓO₂ (0≤x≤1) layer, the difference value ΔE of a d-orbital with respect to Hf or Zr may satisfy 3.5 eV<ΔE<3.8 eV. For example, the difference value ΔE of a d-orbital with respect to Hf or Zr may satisfy 3.6 eV≤ΔE≤3.75 eV. The amorphous thin film 340 may include an amorphous ZrO₂/HZO layer.

The first dielectric layer 331 is provided between the substrate 110 and the amorphous thin film 340, and the second dielectric layer 332 is provided between the amorphous thin film 340 and the gate electrode 150. The first and second dielectric layers 331 and 332 may each include a dielectric material that does not include a ferroelectric. For example, the first and second dielectric layers 331 and 332 may each include a paraelectric material. As a detailed example, the first and second dielectric layers 331 and 332 may each include independently at least one of silicon oxide, silicon nitride, aluminum oxide, silicon oxynitride, lanthanum oxide, yttrium oxide, and/or the like. However, the examples are not limited thereto.

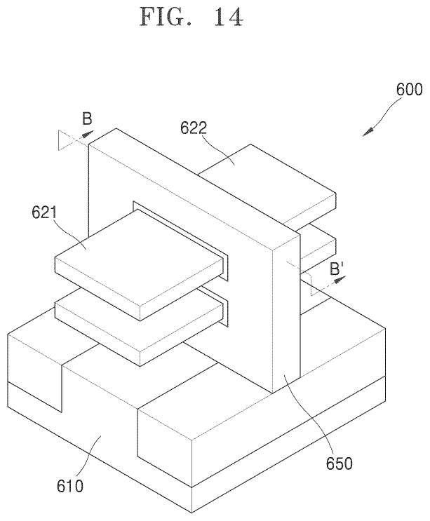

FIG. 11 is a schematic cross-sectional view of a semiconductor device 400 according to at least one embodiment. In FIG. 11, the semiconductor device 400 may include a capacitor. In the following description, differences from the embodiments described above are mainly described.

Referring to FIG. 11, the semiconductor device 400 may include first and second electrodes 410 and 420 provided apart from each other and an amorphous thin film 440 provided between the first and second electrodes 410 and 420. The first and second electrodes 410 and 420 may each include a conductive material. For example, the first and second electrodes 410 and 420 may each include a conductive material, such as a metal, a metal nitride, a metal carbide, polysilicon, a two-dimensional conductive material, and/or the like.

The amorphous thin film 440 may include an amorphous Hf₁₋ₓZrₓO₂ (0≤x≤1) layer. For example, the amorphous thin film 440 may include an amorphous HfO₂ layer, an amorphous ZrO₂ layer, and/or an amorphous HZO layer. In the amorphous Hf₁₋ₓZrₓO₂ (0≤x≤1) layer, the difference value ΔE of a d-orbital with respect to Hf or Zr may satisfy 3.5 eV<ΔE<3.8 eV. For example, the difference value ΔE of a d-orbital with respect to Hf or Zr may satisfy 3.6 eV≤ΔE≤3.75 eV. The amorphous Hf₁₋ₓZrₓO₂ (0≤x≤1) layer may further include, for example, at least one dopant of Si, Al, Y, La, and Gd. The amorphous thin film 440 including the amorphous Hf₁₋ₓZrₓO₂ (0≤x≤1) layer may include, for example, a thickness within a range of 0.5 nm to 20 nm. The amorphous thin film 440 may include an amorphous ZrO₂/HZO layer.

A dielectric layer 430 may be provided between the first electrode 410 and the amorphous thin film 440. The dielectric layer 430 may include a dielectric material that does not include a ferroelectric. For example, the dielectric layer 430 may include a paraelectric material. However, the examples are not limited thereto, and the dielectric layer 430 may not be provided between the first electrode 410 and the amorphous thin film 440, and/or an additional dielectric layer may be provided between the amorphous thin film 440 and the second electrode 420.

In the embodiments described above, the semiconductor devices 100, 200, and 300 in which the channel layer 115 has a planar channel structure are described as examples. However, the disclosure is not limited thereto, and a semiconductor device, in detail, a fin-FET, in which the channel layer has a fin channel structure or a semiconductor device, in detail, a gate-all-around-FET, in which the channel layer has a gate-all-around channel structure, may be provided.

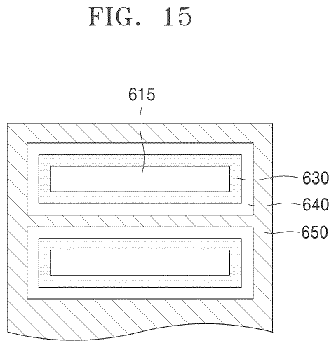

FIG. 12 is a perspective view of a semiconductor device 500, in detail, a fin-FET, according to at least one embodiment, and FIG. 13 is a cross-sectional view of the semiconductor device 500 of FIG. 12 taken along line A-A′.

Referring to FIGS. 12 and 13, source and drain 521 and 522 are provided on both sides of an upper portion of a substrate 510, and a region of the substrate 510 between the source and drain 521 and 522 may be defined as a channel layer 515. The channel layer 515 may have a fin shape. A gate electrode 550 may be disposed to intersect the channel layer 515 having a fin shape. A dielectric layer 530 and the amorphous thin film 340 may be provided between the channel layer 515 and the gate electrode 550 to sequentially surround the channel layer 515.

The amorphous thin film 540 may include an amorphous Hf₁₋ₓZrₓO₂ (0≤x≤1) layer. In the amorphous Hf₁₋ₓZrₓO₂ (0≤x≤1) layer, ΔE of a d-orbital with respect to Hf and/or Zr may satisfy 3.5 eV<ΔE<3.8 eV. The “ΔE” denotes a difference value between the energy of an eg orbital and the energy of a t2g orbital. Specifically, for example, the difference value ΔE of a d-orbital with respect to Hf or Zr may satisfy 3.6 eV≤ΔE≤3.75 eV. The dielectric layer 530 may include, for example, a paraelectric material. The amorphous thin film 540 may include an amorphous ZrO₂ layer/an amorphous HZO layer.

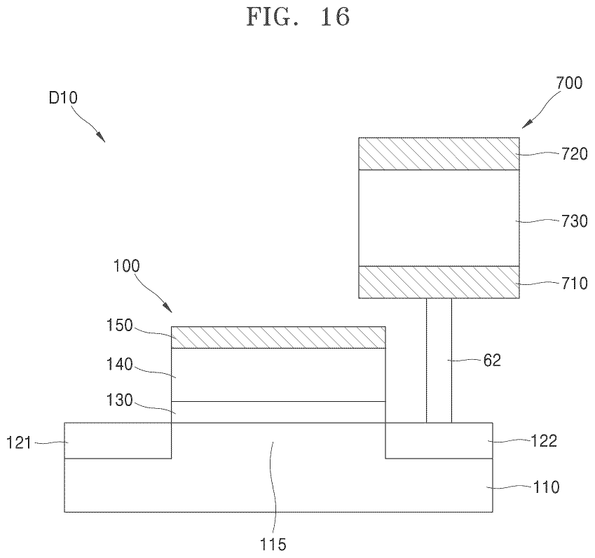

FIG. 14 is a perspective view of a semiconductor device 600, in detail, a gate-all-around-FET, according to at least one embodiment, and FIG. 15 is a cross-sectional view of the semiconductor device 600 of FIG. 14 taken along line B-B′.

Referring to FIGS. 14 and 15, a channel layer 615 is provided between a source 621 and a drain 622, and the channel layer 615 may have a shape of, for example, a sheet or a wire. The source 621, the drain 622, and the channel layer 615 may be disposed apart from a substrate 610. A gate electrode 650 may be disposed to surround the channel layer 615 while intersecting the source 621, the drain 622, and the channel layer 615. A dielectric layer 630 and an amorphous thin film 640 may be provided between the channel layer 615 and the gate electrode 650 to sequentially surround the channel layer 615.

The amorphous thin film 640 may include an amorphous Hf₁₋ₓZrₓO₂ (0≤x≤1) layer. In the amorphous Hf₁₋ₓZrₓO₂ (0≤x≤1) layer, ΔE of a d-orbital with respect to Hf and/or Zr may satisfy 3.5 eV<ΔE<3.8 eV. The “ΔE” denotes a difference value between the energy of an eg orbital and the energy of a t2g orbital. Specifically, for example, the difference value ΔE of a d-orbital with respect to Hf or Zr may satisfy 3.6 eV≤ΔE≤3.75 eV. The dielectric layer 630 may include, for example, a paraelectric material. The amorphous thin film 640 may include an amorphous ZrO₂ layer/an amorphous HZO layer.

According to another aspect of the disclosure, semiconductor apparatuses including the semiconductor devices 100, 200, 300, 400, 500, and 600 described above may be provided. A semiconductor apparatus may include a plurality of semiconductor devices, and may be in the form in which an electric field effect transistor and a capacitor are electrically connected to each other. The semiconductor apparatus may have, for example, memory characteristics of a DRAM device.

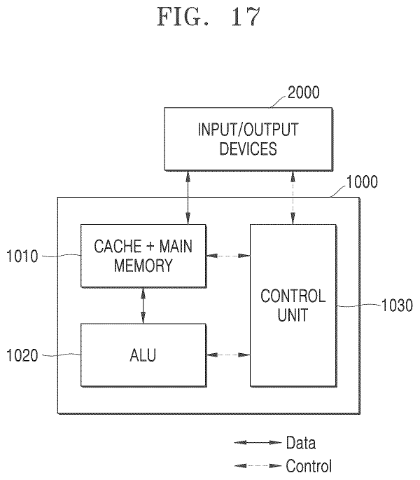

FIG. 16 illustrates a semiconductor apparatus D10 according to at least one embodiment. Referring to FIG. 16, the semiconductor apparatus D10 may have a structure in which an electric field effect transistor (e.g., semiconductor device 100, hereafter referred to as the electric field effect transistor 100) and a capacitor 700 are electrically connected to each other via a contact 62. FIG. 16 illustrates, as an example, a case in which the semiconductor device 100 illustrated in FIG. 1 is used as the electric field effect transistor 100. However, this is just an example, and the semiconductor devices 200, 300, and 400 illustrated in FIGS. 9 to 11, and/or the semiconductor device 500 (fin-FET) illustrated in FIGS. 12 and 13 or the semiconductor device 600 (gate-all-around-FET) illustrated in FIGS. 14 and 15 may be used.

The capacitor 700 may include first and second electrodes 710 and 720 and a dielectric layer 730 provided between the first and second electrodes 710 and 720. One of the first and second electrodes 710 and 720 of the capacitor 700 may be electrically connected to one of source and drain 121 and 122 of the electric field effect transistor 100 via the contact 62. The contact 62 may include a conductive material, for example, tungsten, copper, aluminum, or polysilicon.

The arrangement of the electric field effect transistor 100 and the capacitor 700 may be variously modified. For example, the capacitor 700 may be arranged above the substrate 110, or may have a structure to be embedded in the substrate 110.

The semiconductor apparatus D10 described above may be applied to various electronic apparatuses. For example, the semiconductor apparatus D10 described above may be used for arithmetic operations, program execution, and temporary data retention in electronic apparatuses, such as mobile devices, computers, notebook computers, sensors, network devices, and neuromorphic devices.

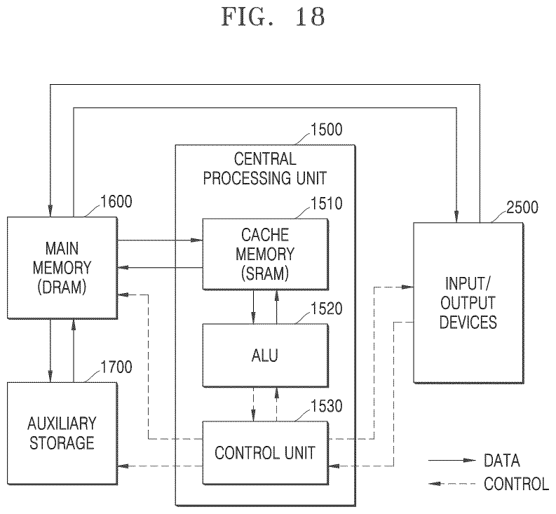

FIGS. 17 and 18 are conceptual block diagrams schematically showing an electronic device architecture 1000 to be applied to an electronic apparatus according to at least one embodiment.

Referring to FIG. 17, the electronic device architecture 1000 may include a memory unit 1010, an arithmetic logic unit (ALU) 1020, and a control unit 1030. The memory unit 1010, the ALU 1020, and the control unit 1030 may be electrically connected to one another. For example, the electronic device architecture 1000 may be implemented as one chip including the memory unit 1010, the ALU 1020, and the control unit 1030. In detail, the memory unit 1010, the ALU 1020, and the control unit 1030 may be connected to one another on-chip via metal lines to communicate directly with one another. The memory unit 1010, the ALU 1020, and the control unit 1030 may be integrated monolithically on a substrate to configure one chip. Input/output devices 2000 may be connected to the electronic device architecture (chip) 1000.

The memory unit 1010, the ALU 1020, and the control unit 1030 may each include independently at least one of the semiconductor devices (the electric field effect transistor, the capacitor, etc.) described above. For example, the ALU 1020 and the control unit 1030 may each include independently the electric field effect transistor described above, and the memory unit 1010 may include the capacitor, the electric field effect transistor, or a combination thereof. The memory unit 1010 may include both of a main memory and a cache memory. The electronic device architecture (chip) 1000 may be an on-chip memory processing unit.

Referring to FIG. 18, a cache memory 1510, an ALU 1520, and a control unit 1530 may configure a central processing unit (CPU) 1500. The cache memory 1510 may consist of static random access memory (SRAM), and include the electric field effect transistor described above. Aside from the CPU 1500, a main memory 1600 and an auxiliary storage 1700 may be provided. The main memory 1600 may consist of dynamic random access memory (DRAM) and include the capacitor described above. Furthermore, Input/output devices 2500 may be provided.

In some cases, the electronic device architecture 1000 may be implemented in the form in which computing unit devices and memory unit devices are adjacent to each other in one chip without distinction of sub-units.

It should be understood that the semiconductor device and the electronic apparatus including the semiconductor device described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate including a channel layer;
a gate electrode over the channel layer; and
an amorphous thin film between the substrate and the gate electrode,
wherein the amorphous thin film includes an amorphous Hf₁₋ₓZrₓO₂ (0≤x≤1) layer,
a difference value ΔE of a d-orbital with respect to at least one of the Hf or the Zr satisfies 3.5 eV<ΔE<3.8 eV, and
the difference value ΔE represents an energy difference between an eg orbital and a t2g orbital with respect to the at least one of the Hf or the Zr.

2. The semiconductor device of claim 1, wherein the difference value ΔE satisfies 3.6 eV≤ΔE≤3.75 eV.

3. The semiconductor device of claim 1, wherein the amorphous thin film further comprises a dopant of at least one of Si, Al, Y, La, or Gd.

4. The semiconductor device of claim 1, wherein the amorphous thin film has a thickness within a range of 0.5 nm to 20 nm.

5. The semiconductor device of claim 1, wherein the amorphous thin film has a thickness within a range of 0.5 nm to 3 nm.

6. The semiconductor device of claim 1, wherein the amorphous thin film has a thickness within a range of 3 nm to 20 nm.

7. The semiconductor device of claim 1, wherein the amorphous thin film comprises an amorphous Hf₁₋ₓZrₓO₂ (0<x<1) layer in which amorphous ZrO₂ and amorphous HfO₂ are alternately stacked.

8. The semiconductor device of claim 1, wherein the amorphous thin film comprises an amorphous ZrO₂ layer on a lower surface of an amorphous Hf₁₋ₓZrₓO₂ (0<x<1) layer.

9. The semiconductor device of claim 1, further comprising:
a source on a first side of the channel layer; and
a drain on a second side of the channel layer.

10. The semiconductor device of claim 1, wherein the channel layer comprises at least one of Si, Ge, SiGe, a group III-V semiconductor, oxide semiconductor, nitride semiconductor, an oxynitride semiconductor, a two-dimensional (2D) semiconductor material, quantum dots, or an organic semiconductor.

11. The semiconductor device of claim 1, wherein the gate electrode comprises at least one of a metal, a conductive metal nitride, a conductive metal carbide, polysilicon, or a two-dimensional conductive material.

12. The semiconductor device of claim 1, further comprising:
a first dielectric layer between the channel layer and the amorphous thin film.

13. The semiconductor device of claim 12, wherein the first dielectric layer comprises at least one of silicon oxide, silicon nitride, aluminum oxide, silicon oxynitride, lanthanum oxide, or yttrium oxide.

14. The semiconductor device of claim 1, further comprising:
a second dielectric layer between the amorphous thin film and the gate electrode.

15. A semiconductor device comprising:
a substrate including a channel layer;
a gate electrode over the channel layer; and
an amorphous thin film provided between the substrate and the gate electrode,
wherein the amorphous thin film comprises an amorphous Hf₁₋ₓZrₓO₂ (0<x<1) layer and an amorphous ZrO₂ layer between the amorphous Hf₁₋ₓZrₓO₂ (0<x<1) layer and the channel layer.

16. The semiconductor device of claim 15, wherein a difference value ΔE of a d-orbital with respect to at least one of the Hf or the Zr in the amorphous Hf₁₋ₓZrₓO₂ (0<x<1) layer satisfies 3.5 eV<ΔE<3.8 eV, and
the difference value ΔE represents an energy difference between an eg orbital and a t2g orbital with respect to the at least one of the Hf or the Zr.

17. The semiconductor device of claim 16, wherein the difference value ΔE satisfies 3.6 eV≤ΔE≤3.75 eV.

18. The semiconductor device of claim 15, wherein the amorphous thin film further comprises a dopant of at least one of Si, Al, Y, La, or Gd.

19. The semiconductor device of claim 15, wherein the amorphous thin film has a thickness within a range of 0.5 nm to 20 nm.

20. An electronic apparatus comprising the semiconductor device of claim 1.
